(19) United States
(12) Patent Application Publication
(10) Pub. No.: US 2003/0234444 A1
(43) Pub. Date: Dec. 25, 2003

(54) Lead frame

(76) Inventors: Jeremy Paul Smith, Wollaston Village (GB); Terence Michael O'Connor, Bedford (GB)

Correspondence Address: KLEIN, O'NEILL & SINGH, 2 PARK PLAZA, SUITE 510, IRVINE, CA, 92614, US

(21) Appl. No.: 10/457,221

(22) Filed: Jun. 9, 2003

(30) Foreign Application Priority Data
Jun. 7, 2002 (GB) 0213094.6

(51) Int. Cl. H01L 23/48

(52) U.S. Cl. 257/690

(57) ABSTRACT

A semiconductor package (19) comprises a semiconductor chip (112) and a clip (116) and a lead frame (114) for electrically supporting the chip within the semiconductor package. The chip has at least two solder pads (120, 150) on one surface, and either or both the lead frame and clip have corresponding pedestals. Each solder pad is soldered to a respective pedestal (128, 158) on one of said lead frame and clip for supporting the chip (112) during assembly of the semiconductor package (19).

### BACKGROUND OF THE INVENTION

1. Field of the Invention

The present invention relates to a conductive substrate, normally termed a lead frame, and a semiconductor package using such a conductive substrate.

2. Description of the Prior Art

In order to reduce component cost and increase component circuit density, it is normal to fit more than one semiconductor chip into a semiconductor package. Many semiconductor packages use a conductive substrate, termed a lead frame, as a mounting surface for the semiconductor chips.

### BRIEF SUMMARY OF THE INVENTION

The present invention seeks to provide an improved lead frame and improved semiconductor package.

Accordingly, the present invention provides a lead frame for use in a semiconductor package, the lead frame having at least two pedestals for supporting a chip during assembly of a semiconductor package.

The present invention also provides a conductive clip for a semiconductor package, the clip having at least two pedestals for electrically contacting a chip and supporting the chip during manufacture of a semiconductor package.

The present invention also provides a semiconductor chip for a semiconductor package, the chip having at least two solderable pads for electrically contacting a lead frame for supporting the chip during manufacture of a semiconductor package.

The present invention also provides a semiconductor package comprising a semiconductor chip and a clip and lead frame for electrically supporting the chip within the semiconductor package, wherein the chip has at least two solder pads on one surface thereof each of which is soldered to a respective pedestal on one of said lead frame and clip.

### BRIEF DESCRIPTION OF THE DRAWINGS

The present invention is further described hereinafter, by way of example, with reference to the accompanying drawings, in which:

FIG. 1 is a partial section through a conventional semiconductor package;

FIG. 2 is a plan view of an upper surface of a chip of the package of FIG. 1; and

FIG. 3 is a inverse plan view of the chip of FIG. 2;

FIG. 4 is a partial section through a semiconductor package embodying a preferred form of the invention;

FIG. 5 is a plan view of an upper surface of a chip of the package of FIG. 4; and

FIG. 6 is a inverse plan view of the chip of FIG. 5.

### DETAILED DESCRIPTION

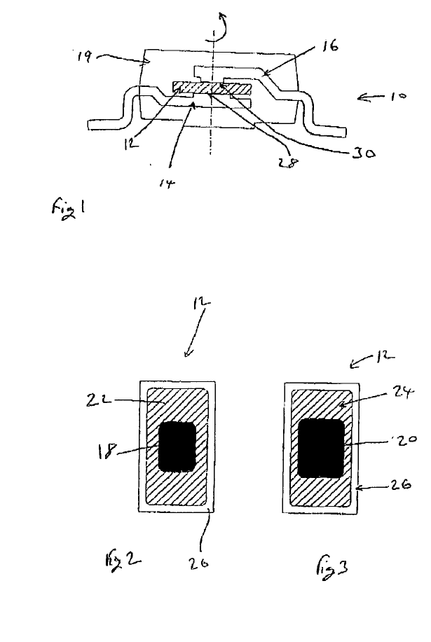

FIG. 1 is a partial section through a semiconductor package 10 having several semiconductor chips 12 (only of one of which is shown) mounted on a conventional lead frame 14. Electrical connection to each chip within the package is made by way of the lead frame 14 on one side (the underside) of each chip and a conductive formed clip 16 on the other (upper) side of each chip. The chip, lead frame and clip are all embedded in a moulded polymer insulation 19 to form the semiconductor package.

FIGS. 2 and 3 are respectively plan views of the upper and lower surfaces of one chip 12. Each surface has a metallisation which is normally chosen as a combination of metal layers. These are typically four layers which may be patterned by etching through suitable masks. The top one or two layers are chosen to be solderable to tin based solders and form a solderable pad or metal area 18, 20 which is surrounded by an area of metal 22, 24 which is resistant to soldering. The metal areas 22, 24 are formed by the middle layers of the metallisation. The dimensions of the solderable metal areas 18, 20 are designed to match the areas of the pedestals on the lead frame and clip.

The chip shown in FIGS. 2 and 3 is designed for high voltage operation and has a periphery 26 which is designed to sustain the applied voltage. This voltage sustaining peripheral region 26 must be electrically isolated from the lead frame and the clip 16 and this is effected by the formation of a raised area or pedestal 28, 30 on each of the lead frame 14 and clip 16. The dimensions of the pedestals are such that they lie within the area 22 (ideally matching the areas 18, 20) and do not contact the voltage sustaining periphery 26.

The solders used to solder the chips to the lead frame and clip generally contain a proportion of tin and the materials of the lead frame and chip metalisation are chosen to offer good solderability to such solders.

During the soldering operation, the solder forms a liquid layer between the chip and the lead frame and clip. The only forces supporting the chip at this time and retaining it in position are the wetting forces and surface tension arising from metallurgical interaction between the solder and the metals of the chip surface, the lead frame and clip. When several chips are soldered into a single semiconductor package these forces may not be sufficient to prevent rotation or lateral movement of each chip, particularly as the pedestals and the solder pads 18, 20 of the chip, lead frame and clip lie on the same axis of rotation. As a result, there is a possibility of adjacent chips contacting one another. It is also possible for a chip to be displaced or rotated sufficiently to bring the chip or a part of a chip too close to the external surface of the moulded polymer 19 which may in turn effect the functionality of the chip over its useful life.

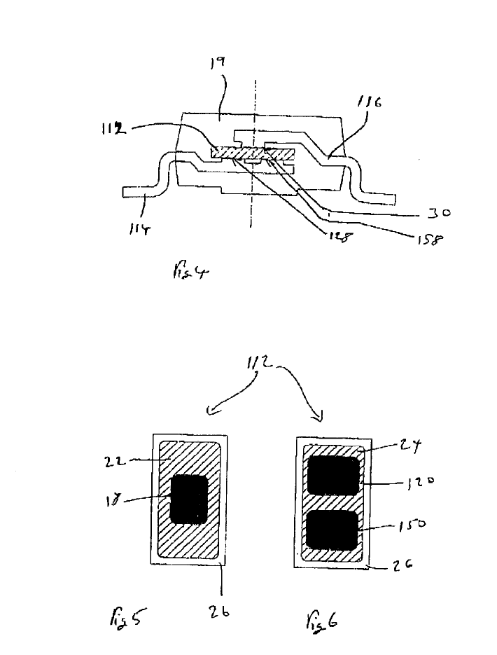

The semiconductor package shown in FIG. 4 is similar to that of FIG. 1 having a lead frame 114 and a clip 116 mounting a semiconductor chip 112, the whole being embedded within moulded polymer 19.

However, as can be seen from FIG. 6 each chip 112 in the package has two metalised, solderable pads 120, 150 surrounded by the area 24 and the peripheral region 26. The pads 120, 150 are formed in the same manner as the area 20 of FIG. 3. The upper surface of the chip carries a single solderable metalised pad 18 and as can be seen, in this example, the arrangement of the metalised layers 18, 120, 150 and the voltage sustaining region 26 is the same as shown in FIG. 2.

Referring again to FIG. 4, the lead frame 114 is shown as having two pedestals 128, 158 each of which is intended to contact a respective one of the metalised areas 120, 150 of the chip 112.

During manufacture, the pedestals 128, 158 of the lead frame 114 would be soldered to the respective pads 120, 150 of the chip. The pedestal 30 of the clip 116 would be soldered to be pad 18.

Each chip 12 is therefore soldered in three areas, two on the chip undersurface and one on the upper surface. This arrangement reduces the possibility of rotation or movement of the chip during soldering, particularly with the solderable areas on the undersurface of the chip no longer being in the same axis of rotation as the solderable area on the top of the chip.

It will be appreciated that the chip may have two or more solderable pads on its upper or lower surface or on both surfaces for soldering to corresponding pedestals on the clip and lead frame. The solderable pads may also be part of a single continuous region with narrower sections connecting the areas which form the pads, for example, two overlapping circular pads in an approximate ‘8’ shape. It is also possible for the clip to have two or more pedestals and the lead frame only one, or both the lead frame and clip to have two or more pedestals

In one preferred embodiment, not shown in the drawings, only one pad is formed on the upper and lower chip surfaces with one pedestal on each of the lead frame and clip. However, the axes of rotation of the pedestals and pads are such that at least two are misaligned.

1. A connection means (114, 116) for use in a semiconductor package (19), the connection means having at least two pedestals (128, 158; 18) for supporting a chip (112) during assembly of the semiconductor package (19).

2. A connection means as claimed in claim 1 being a lead frame (114) for the chip (112).

3. A connection means as claimed in claim 1 being a clip (116) for the chip (112).

4. A semiconductor chip (112) for a semiconductor package (19), the chip having upper and lower surfaces and at least two solderable pads (120, 150) on one of said surfaces thereof for electrically contacting a lead frame (114) or clip (116) and for supporting the chip during manufacture of the semiconductor package.

5. A semiconductor chip as claimed in claim 4 having at least two solderable pads (120, 150) on each of said surfaces thereof for electrically contacting a lead frame (114) and a clip (116) and for supporting the chip during manufacture of the semiconductor package.

6. A semiconductor chip as claimed in claim 4 or 5 wherein said solderable pads (120, 150) on said one or each surface are connected by narrow regions of solderable material

7. A semiconductor chip as claimed in claim 4 or 5 wherein said solderable pads (120, 150) on said one or each surface are separated by regions of solder resistant material.

8. A semiconductor package (19) comprising a semiconductor chip (112) and a clip (116) and a lead frame (114) for electrically supporting the chip within the semiconductor package, wherein the chip has at least two solder pads (120, 150) on one surface thereof, each of which is soldered to a respective pedestal (128, 158) on one of said lead frame and clip.

9. A semiconductor package (19) comprising a semiconductor chip (112), a clip (116) and a lead frame (114) for electrically supporting the chip (112) within the semiconductor package, wherein the chip (112) has:
at least one lead frame pad (20, 120, 150) on one surface thereof, the or each lead frame pad (20, 120, 150) being soldered to a corresponding pedestal (128, 158) of the lead frame (114),
and at least one clip pad (18) on the opposite surface thereof, the or each clip pad (18) being soldered to a corresponding pedestal (30) of the clip (116);
and wherein the or at least one lead frame pad (20, 120, 150) is laterally offset from the or at least one clip pad (18).

10. A semiconductor package according to claim 9 in which at least one of the lead frame pad arrangement and the clip pad arrangement is in the form of two or more pads on one surface of the chip (112), separated by regions of solder resistant material.

11. A semiconductor package according to claim 9 in which at least one of the lead frame pad arrangement and the clip pad arrangement is in the form of two or more pads on one surface of the chip (112) connected by narrow regions of solderable material.

12. A semiconductor package according to any of claims 9, 10 or 11 in which there are two or more said chips (112).
